(19) United States
(12) Patent Application Publication
(10) Pub. No.: US 2021/0302245 A1
(43) Pub. Date: Sep. 30, 2021

(54) A DEVICE AND METHOD FOR GENERATING A SUPERCONTINUUM

(71) Applicant: Singapore University of Technology and Design, Singapore (SG)

(72) Inventors: Dawn Tan, Singapore (SG); Ezgi Sahin, Singapore (SG); Benjamin Eggleton, Sydney (AU)

(21) Appl. No.: 16/835,337

(22) Filed: Mar. 31, 2020

(51) Int. Cl. G01L 1/24; G02F 1/365; G02F 1/35; G02B 6/122; G02B 6/34; G02B 27/58; H01L 27/15; H01L 21/02

(52) U.S. Cl. CPC G01L 1/246; G02F 1/365; G02F 1/3513; G02B 6/1225; G02B 2006/12107; G02B 27/58; H01L 27/15; H01L 21/02164; H01L 21/0217; G02B 6/34

(57) ABSTRACT

According to various embodiments, a photonic device and method for generating supercontinuum pulses are provided. The photonic device includes two stages, a nonlinear Bragg grating, and a nonlinear waveguide, which may be formed from CMOS-compatible ultra-rich silicon nitride using a monolithically integrated design.

### TECHNICAL FIELD

The various embodiments generally relate to photonic devices for generating a supercontinuum.

### BACKGROUND

Supercontinuum generation has applications in a wide range of areas including metrology, telecommunications, hyperspectral imaging, and optical coherence tomography. A supercontinuum occurs through the interaction of many nonlinear processes, such as self-phase modulation, four-wave mixing, and soliton based dynamics, to cause extensive spectral broadening.

It is well understood that solitons underpin crucial applications in ultrafast optics, communications and signal processing. While fundamental solitons preserve their shape during propagation, high-order solitons evolve periodically due to the interplay of linear dispersion and Kerr effects in the material. This periodic evolution involves temporal compression, pulse splitting, and recovery of the initial soliton pulse shape. A strong perturbation in the system can break this periodicity and initiate soliton fission, which manifests as pulse break up and pulse train generation.

Soliton fission, which is also one of the underlying physical effects involved in supercontinuum generation, introduces pulse modulations in time, compression and splitting, giving rise to spectral broadening and new peaks in the spectrum. One-dimensional solitons supported by the strong dispersion on a Bragg grating's band edge, also known as “Bragg solitons”, propagate well down optical fibers, but not through silicon chips, due to strong nonlinear absorption effects. CMOS platforms are constrained by inherent material properties. For example, silicon waveguides possess non-negligible nonlinear losses and traditional silicon nitride has low optical nonlinearity. Therefore, the efficient generation of supercontinuum will depend on the device design and on the dispersion and nonlinear parameters of the materials used for developing a CMOS-compatible photonic device.

### SUMMARY

The embodiments described herein generally relate to an integrated photonic chip having a substrate with a nonlinear Bragg grating coupled to the optical pulse source, and a nonlinear waveguide coupled to the nonlinear Bragg grating. The nonlinear Bragg grating has two nonlinear rows of columnated-structures and an elongated structure, wherein the elongated structure separates the two nonlinear rows of columnated-structures. The nonlinear Bragg grating and nonlinear waveguide may be formed of an ultra-silicon rich nitride material and are monolithically integrated.

According to various embodiments, a method for generating a broadband supercontinuum may provide an optical pulse of a predetermined wavelength and inputting the optical pulse through a nonlinear Bragg grating to effect apodizing and soliton propagation. The optical pulse continues through a nonlinear waveguide and the output from the nonlinear waveguide is an octave-spanning optical pulse.

According to various embodiments, a photonic device may have a substrate with a first silicon dioxide layer that forms a lower cladding for a nonlinear Bragg grating structure having an ultra-silicon rich nitride elongated structure between two nonlinear rows of columnated structures and for a nonlinear waveguide extending from the elongated structure thereon and a second silicon dioxide layer upper cladding thereover.

These and other advantages and features of the embodiments herein disclosed will be apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. The drawings are also not necessarily to scale, emphasis instead generally being placed upon illustrating the principles of the invention. The dimensions of the various features or elements may be arbitrarily expanded or reduced for clarity. In the following description, various embodiments of the invention are described with reference to the following drawings, in which:

FIG. 1 shows a simplified plan view of the top of an embodiment of the photonic device according to the present disclosure;

FIG. 2 shows a simplified plan view of the top of an embodiment of a Bragg grating structure according to the present disclosure.

FIG. 3 shows a simplified plan view of the top of an embodiment of the cladded photonic device according to the present disclosure, and the associated FIGS. 3a through 3c show cross-sectional views thereof;

FIG. 4 shows a diagram illustrating a perspective view of an embodiment of the Bragg grating structure according to the present disclosure; FIGS. 5A through 5C show spectral profiles for measurements and simulations for an embodiment of the two-stage photonic device according to the present disclosure; and

FIGS. 6A through 6C show alternative embodiments for a Bragg grating according to the present disclosure.

### DETAILED DESCRIPTION

The following detailed description refers to the accompanying drawings that show, by way of illustration, specific details and embodiments in which the present disclosure may be practiced. These embodiments are described in sufficient detail to enable those skilled in the art to practice the present disclosure. Other embodiments may be utilized and structural, and logical changes may be made without departing from the scope of the present disclosure. The various embodiments are not necessarily mutually exclusive, as some embodiments can be combined with one or more other embodiments to form new embodiments.

It will be understood that any property described herein for a specific device may also hold for any device described herein. It will be understood that any property described herein for a specific method may also hold for any method described herein. Furthermore, it will be understood that for any device or method described herein, not necessarily all the components or steps described must be enclosed in the device or method, but only some (but not all) components or steps may be enclosed.

In order that the present disclosure may be readily understood and put into practical effect, particular embodiments will now be described by way of examples and not limitations, and with reference to the figures.

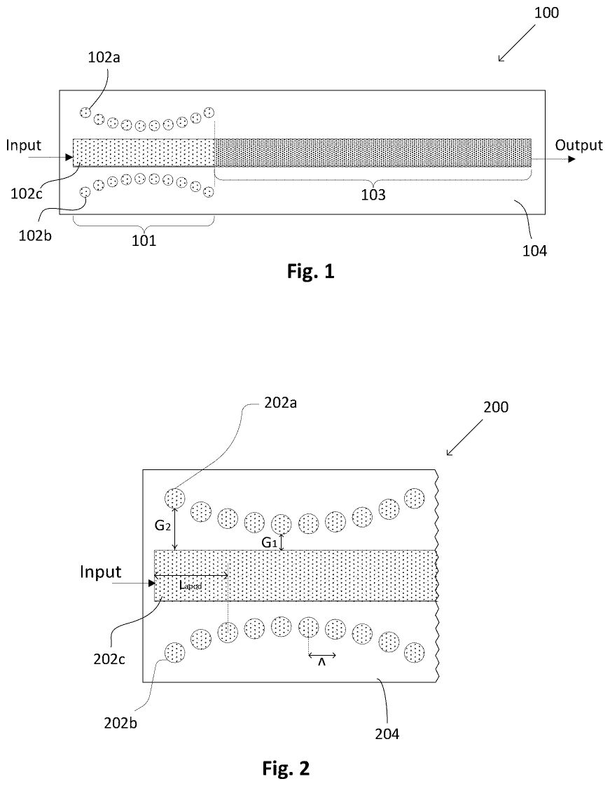

FIG. 1 shows a simplified plan view of the top of a photonics device 100 according to an embodiment of the present disclosure. The photonic device 100 may have two-stages including a nonlinear Bragg grating structure 101 and a nonlinear waveguide structure 103 that are positioned over a silicon dioxide layer 104. The silicon dioxide layer 104 is the lower cladding for the photonic device 100. The nonlinear Bragg grating structure 101 may have two rows of columnated-structures 102a and 102b and an elongated structure 102c positioned therebetween. When fully cladded with a covering of an upper silicon dioxide layer, the present Bragg grating may be referred to as a nonlinear cladding modulated Bragg grating (CMBG).

In the various embodiments, the columnated-structures may be a plurality of pillars or columns that are aligned and spaced apart according to the desired pattern. According to an embodiment, the two rows of columnated-structures 102a and 102b and the elongated structure 102c are coplanar and monolithically integrated, i.e., made during a single lithographic patterning step. Also, the two rows of columnated-structures 102a and 102b and the elongated structure 102c may be formed from the same material.

According to another embodiment, the elongated structure 102c and the nonlinear waveguide structure 103 may be coplanar and monolithically integrated, i.e., made during a single lithographic patterning step. The elongated structure 102c and the nonlinear waveguide structure 103 channel the optical pulses for supercontinuum generation. The elongated structure 102c and the nonlinear waveguide structure 103 may be a unitary structure and formed from the same material, although it is possible to use different (but compatible) materials for the elongated structure 102c and the nonlinear waveguide structure 103.

The material used for forming the nonlinear Bragg grating structure 101 and the nonlinear waveguide structure 103 may be an ultra-silicon-rich nitride (hereinafter “the USRN”), which, specifically, has the chemical formula Si₇N₃. The typical or ordinary silicon nitride used in semiconductor devices has the chemical formula Si₃N₄. The USRN has the property of a Kerr nonlinearity (i.e., a light-induced change in refractive index) that is an order of magnitude higher than the ordinary silicon nitride (i.e., n₂=2.8×10-13 cm²W-1). Alternatively, the USRN may have a range of refractive indices that range from 2.1 to 3.3 to obtain the desired Kerr nonlinearity.

It is within the scope of the present disclosure to use other CMOS-compatible materials, such as various forms of silicon nitrides, silicon oxynitrides, and silicon-rich nitrides. In other embodiments, materials for making the Bragg grating structure and waveguide structure may include III-V materials (e.g., gallium arsenide, gallium nitride, indium nitride), group IV materials (e.g., silicon, polysilicon, germanium, silicon carbide, graphene), and chalcogenides, which may be considered to be “non-CMOS-compatible”.

Advantageously, the use of the USRN in present photonic device design allows the nonlinear loss limitations found in silicon, for example, at the 1.55 μm wavelength region, enabling retention of a large nonlinearity and low nonlinear absorption. This is due to the optical properties of the USRN that provide a sufficiently large bandgap to eliminate two-photon absorption and preserve the efficiency of optical processes. In various embodiments of the present disclosure, the elongated structure of the nonlinear Bragg grating is an ultra silicon-rich nitride elongated structure.

An optical pulse source (not shown) provides an input pulse that enters the proximal end of the elongated structure 102c and travels its length and then through the nonlinear waveguide structure 103. The optical pulse source may be a component on the present photonic chip or a separate chip. The Bragg solitons that are generated will be highly confined and will propagate in the nonlinear waveguide 103. The Bragg solitons propagate at the frequencies just outside of the stop-band (i.e., on the blue side, or short wavelength side) are induced by the two-row of columnated-structures, i.e., the coupling of forward and backward propagating optical fields as a result of the Bragg grating results in a region of high dispersion and high transmissivity just outside of the grating band edge. This “apodization” enables the transmission spectrum of the grating to be “clean”, which means to have minimal ripple/oscillations both outside and inside of the bandgap.

In the first stage nonlinear Bragg grating structure, the large second and third order engineered dispersion are used to initiate the soliton-effect and soliton fission. The soliton fission process causes the primary high-order soliton to break down into multiple secondary solitons. These multiple secondary solitons propagate into the second stage, nonlinear waveguide structure. The secondary solitons have a narrow temporal width and relatively high peak power. Accordingly, the present photonic device may be able to generate broadband supercontinuum or octave-spanning optical pulses at a far greater efficiency, i.e., less expensive and less complex to generate.

In addition, tuning the extent of spectral broadening may be effected using temperature, which, through the thermo-optic effect, increases or decreases the separation between the source pulse and the grating band edge. By changing the temperature conditions so that the source pulses are closer to the grating band edge, i.e., tuning the band edge, thermo-optic tuning of the spectral broadening may be achieved.

FIG. 2 shows a simplified plan view of the top of an embodiment of a Bragg grating structure 200 according to the present disclosure. The nonlinear Bragg grating structure 200 may have two rows of columnated-structures 202a and 202b with the elongated structure 202c between them. As also shown in FIG. 2, the two rows of columnated-structures 202a and 202b may be a plurality of regularly spaced columns positioned in a nonlinear pattern, which, in this embodiment, is a bow-shaped curve having a proximal end, a middle portion, and a distal end.

The location of the two rows may be determined by (1) the Bragg conditions, which determines the distance between each columnated structure; and (2) the apodization function, which determines the distance between the elongated structure and each columnated structure, as discussed below.

While the bow-shaped curve is specifically disclosed, other alternative embodiments may include shapes that may produce Blackman apodization or cosine apodization. For the columnated-structures used for the present Bragg grating, the columnated structures may be separated further from the center elongated waveguide structures at the ends, while getting closer to the center elongated waveguide towards the middle portion thereof.

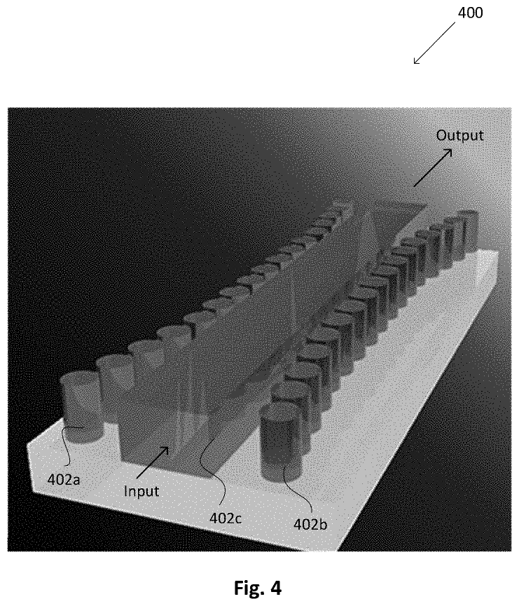

According to an embodiment of the present photonic device, the two rows of columnated-structures 202a and 202b may have a plurality of round shaped columns, as also shown in FIG. 4. It is within the scope of the present disclosure to use columns having other shapes; for example, shapes such as squares, hexagons, octagons, etc. may also be used. In another aspect, the present Bragg grating may also be apodized by making the diameter of the columnated-structures smaller at the input (i.e., proximal) and output (i.e., distal) ends, and then progressively larger in diameter towards the center of the center elongated waveguide structure (i.e., middle portion).

The modulation of the distance between the columns changes the effective refractive index (n_{eff}) perturbation. Avoiding an abrupt change in n_{eff} eliminates the out of band ripples as the apodization suppresses the grating sidelobes without influencing the Bragg wavelength (λB=2n_{eff}Λ). The parameters are the apodization length (L_{apod}), pitch (Λ), gaps (G₁ & G₂), effective refractive index (n_{eff}) seen by the pulse traveling in the present Bragg grating having of length L. The Bragg grating design uses the equation as given in Equation 1 below:

$$G ( z ) = ( {G}_{2} - {G}_{1} ) \times {cos}^{2} ( π x ) + {G}_{1} where x = \{ \begin{matrix}\frac{z}{2 {L}_{apod}} if z \leq {L}_{apod} \\ 0.5 if {L}_{apod} < z < L - {L}_{apod} \\ \frac{z - {L}_{apod}}{2 {L}_{apod}} if z \geq L - {L}_{apod}\end{matrix} \qquad ( 1 )$$

where G(z) is the distance between the columnated-structures and the center elongated waveguide, z is the coordinate in the direction of the center elongated waveguide, and x is a variable dependent on the position z.

For example, soliton propagation may be modeled for the various embodiments of the present photonic device using the generalized nonlinear Schrödinger equation given in Equation 2 below:

$$\frac{\partial A}{\partial z} + \frac{α}{2} A + \frac{i {β}_{2}}{2} \frac{{\partial }^{2} A}{\partial {T}^{2}} - \frac{{β}_{2}}{6} \frac{{\partial }^{z} A}{\partial {T}^{4}} - \frac{i {β}_{4}}{24} \frac{{\partial }^{4} A}{\partial {T}^{4}} = i {γ}_{eff} ( {\vert A \vert}^{2} A ) \qquad ( 2 )$$

where β₂ is the group velocity dispersion, β₃ is the third-order dispersion curve, β₄ is the fourth-order dispersion curve, A is the slowly varying pulse envelope, a is the linear absorption, z is the propagation direction, T is a time coordinate measured as a frame of reference moving with the pulse at the group velocity, v_{g} (T=t−z/v_{g}), and γ_{eff} is the effective nonlinear parameter of the waveguide.

By employing a split-step Fourier method to solve Equation 2 above, it is possible to interpret the underlying physics in soliton propagation. The right-hand side of Equation 2 takes into account effects from self-phase modulation. As shown, γ_{eff} denotes the effective nonlinear parameter and is calculated as given in Equation 3 below:

$${γ}_{eff} = \frac{{ω}_{o} {n}_{2}}{λ {A}_{eff}} {( \frac{{n}_{g}}{{n}_{o}} )}^{2} \qquad ( 3 )$$

where ω₀ is the frequency of the pulse, n_{g} is the group index and nₒ is the refractive index of the material.

According to one embodiment, the effective area (A_{eff}) may be engineered to be small to maximize the magnitude of γ_{eff}. Nonlinear losses will be negligible at optical intensities up to 50 GW/cm2 for the present photonic device and, therefore, only linear propagation losses, α, will need to be taken into account. The data may be obtained to show the loss parameter α as being 13 dB/cm for the first stage nonlinear Bragg grating and 4.5 dB/cm for the second-stage nonlinear waveguide.

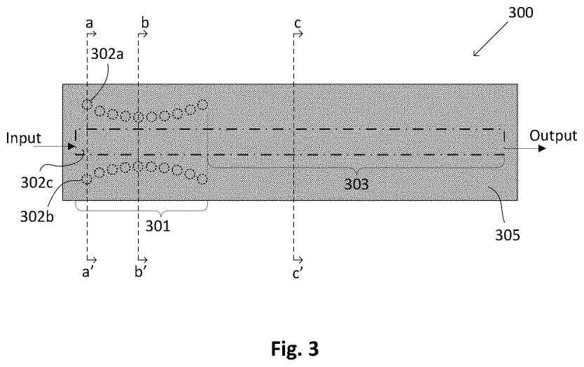

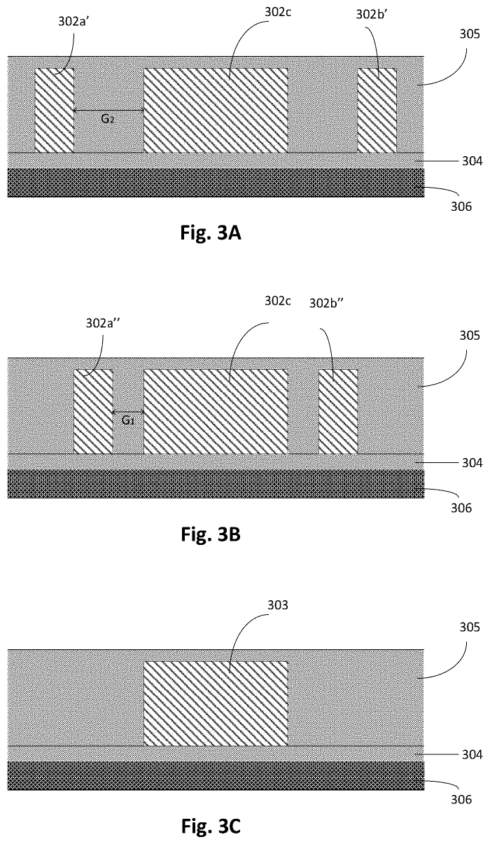

FIG. 3 shows a simplified plan view of a top of an embodiment of the photonic device 300 with an upper layer of silicon dioxide 305 that provides an upper cladding for the device 300. A nonlinear Bragg grating 301 and nonlinear waveguide 303 (both shown in dashed lines) are buried under a silicon dioxide layer 305.

In addition, for the embodiment shown in FIG. 3, the FIGS. 3a through 3c present cross-sectional views along certain section lines. FIG. 3a provides the view along section line a-a′ at the proximal end of the Bragg grating 301, through the two rows of columnated-structures 302a and 302b and elongated structure 302c, and a substrate 306. The separation between two rows of columnated-structures 302a′ and 302b′ and elongated structure 302c at the proximal end is G₂.

FIG. 3b provides the view along section line b-b′ at the middle portion of the Bragg grating 301, through the two rows of columnated-structures 302a and 302b and elongated structure 302c, and a substrate 306. The separation between two rows of columnated-structures 302a″ and 302b″ and elongated structure 302c at the middle portion is G₁.

FIG. 3c provides the view along section line c-c′ on the waveguide 303, which fully cladded, i.e., buried, by the silicon dioxide layers 304 and 305.

From the cross-sectional views, the fabrication for this embodiment of the present photonic device may be discussed. The Bragg grating structure and the waveguide structure may be formed by a standard lithographic process. In an aspect of the embodiment, no sacrificial etching process is used for the Bragg grating, which causes it to be more structurally robust; in particular, the two rows of columnated-structures.

According to an embodiment of the present disclosure, a silicon dioxide layer 304 may be grown by thermal oxidation from the substrate 306. A USRN layer may be deposited on the silicon dioxide layer 304 using inductively-coupled chemical vapor deposition. Thereafter, the Bragg grating structure and the waveguide structure may be formed by patterning the USRN layer using electron-beam lithography, i.e., an inductively coupled plasma etching. Finally, the upper cladding provided by a silicon dioxide layer 305 may be formed using atomic layer deposition and/or plasma-enhanced chemical vapor deposition.

The fabrication methods and the choice of materials are intended to permit the present photonic devices to be CMOS-compatible. Also, non-CMOS-compatible fabrication techniques may be used when the selected materials or desired applications are directed toward such techniques. It will be apparent to those ordinary skilled practitioners that the foregoing process steps may be modified without departing from the spirit of the present disclosure.

In exemplary embodiments of the present two-stage photonic device, the dimensions for the two-stage Bragg grating structure and the waveguide structure may have a Bragg grating structure with an ultra-silicon rich nitride elongated structure that may have a thickness in the range of approximately 100 nm to tens of microns and may have a length in the range of 200 μm to 10 mm. In other embodiments, a nonlinear waveguide structure, which may be an extension of the ultra-silicon rich nitride elongated structure, may have a length in the range of approximately 1 mm to 10 cm. In some embodiments, a nonlinear waveguide structure may have a length up to several centimeters and may be further dependent on the length for a substrate support or the refractive index of the material used. In another embodiment, a Bragg grating structure may have two nonlinear rows of column structures that may have a length in the range of 200 μm to 10 mm, and in other embodiments, each of the two nonlinear rows of columnated-structures may have a proximal end positioned approximately 50 nm to 100 nm from the ultra-silicon rich nitride elongated structure and a middle portion positioned approximately 20 nm to 150 nm from the ultra-silicon rich nitride elongated structure. In yet another embodiment, the two nonlinear rows of column structures may have an adjustable grating pitch in the range of approximately 300 nm to 500 nm. In a further embodiment, a first silicon dioxide layer may have a thickness in the range of 2 um to 20 μm and a second silicon dioxide layer has a thickness in the range of 3 um to 20 um.

In a specific embodiment of the present two-stage photonic device, the dimensions for a two-stage Bragg grating structure and a waveguide structure may have a Bragg grating structure with an ultra-silicon rich nitride elongated structure that may have a thickness of approximately 300 and a length of approximately 1 mm, a nonlinear waveguide structure may have a thickness of approximately 300 and a length of approximately 6 mm, two nonlinear rows of column structures may have a length of approximately 1 mm, and each of the two nonlinear rows of columnated-structures may having proximal and distal ends that may be positioned approximately 100 nm from the ultra-silicon rich nitride elongated structure and a middle portion positioned approximately 50 nm from the ultra-silicon rich nitride elongated structure, and may have an adjustable grating pitch of approximately 339 nm. In a specific embodiment for the cladding, the first silicon dioxide layer may have a thickness of approximately 10 μm and a second silicon dioxide layer may have a thickness of approximately 2 um.

In another specific embodiment of the present two-stage photonic device, a two-stage Bragg grating structure and waveguide structure may have a footprint of 8.8×10⁻⁹ m².

FIG. 4 shows a perspective illustration of an embodiment of a Bragg grating structure 400 that is shown without an upper cladding of silicon dioxide. The nonlinear Bragg grating structure 400 has two rows of column structures 402a and b with an elongated structure 402c between them. Similar to the embodiment shown in FIG. 2, the two rows of column structures 402a and b are positioned in a nonlinear bow-shaped curve. This unique cladding-modulated Bragg grating design allows for effective apodization in the input and output ends of the grating structure 400 to minimize sidelobes and ensure low insertion loss at frequencies close to the stop-band.

As shown by the representational spectral profiles in FIG. 5a-c, experimental results were generated utilizing third-order dispersion to induce soliton fission to augment supercontinuum generation using the present two-stage photonic device design. By providing 1.68 ps input pulses, the resulting output was approximately 311 nm of supercontinuum with having a low coupled peak power of 5.47 W.

In FIG. 5A, the spectrum of an input picosecond pulse that was used to generate the experimental data is shown. In FIG. 5B, the output spectrum of the reference waveguide of length 7 mm (i.e., without a Bragg grating) that used for comparison against the various embodiments of the present photonic device. In FIG. 5C, the resulting output of a two-stage nonlinear Bragg grating and a nonlinear waveguide structure of the present disclosure shows large spectral broadening with approximately four-times (4×) enhancement compared to the reference waveguide, i.e., from approximately 79 nm using the reference waveguide to approximately 311 nm using an embodiment of the present photonic device.

Also, the nonlinear Bragg gratings of the present disclosure allow dispersion engineering by providing wide flexibility for achieving complex gratings via their tunable parameters, such as column radius, gaps between the columnated rows and the waveguide, and grating pitch (Λ), as discussed above. By exploiting the high order soliton dynamics available using the present photonic device consisting of a nonlinear Bragg grating and nonlinear waveguide, a wide supercontinuum may be generated without the need to use sub-picosecond pulses or increasing the device footprint.

According to an embodiment of the present disclosure, the two-stage photonic device will be incorporated as part of an integrated photonic chip. The integrated photonic chip may comprise a range of additional devices, including an on-chip optical source, low loss interconnect waveguides, power splitters, optical amplifiers, optical modulators, filters, lasers, and detectors. Accordingly, the use of supercontinuum generation in applications such as metrology, telecommunications, hyperspectral imaging, and optical coherence tomography will require components specific to their individual needs.

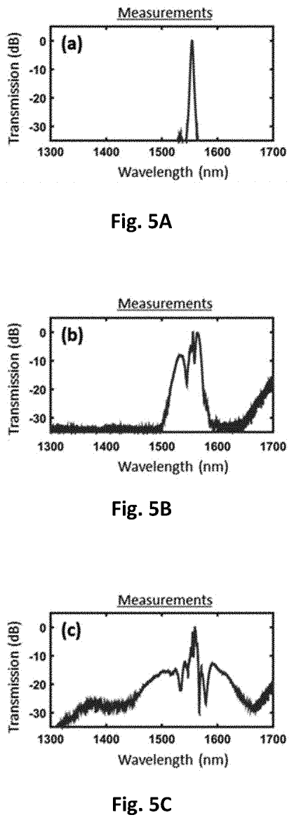

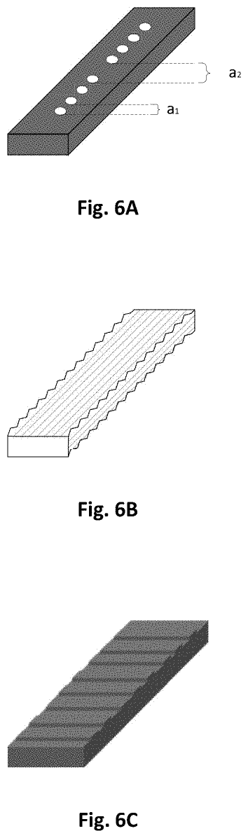

As shown in FIG. 6, it is within the scope of the present disclosure to use Bragg gratings that may have different structures. For example, according to various embodiments, a Bragg grating may periodic holes, which may have varying pitches a₁ and a₂, as shown in FIG. 6A, or be a sidewall modulated Bragg grating as shown in FIG. 6B, or be a “surface relief” Bragg gratings (i.e., top of the is periodically corrugated) as shown in FIG. 6C.

More specifically, the present monolithically integrated photonic chip design includes two-stages of a nonlinear cladding modulated Bragg grating (CMBG) of length 1 mm followed by a 6 mm long buried channel nonlinear waveguide. The CMBG has a waveguide with pillars placed adjacent to it with a distance defined with the gap parameter (G). The pillar positioning modulates the effective refractive index seen by the light propagating within the waveguide. Tailoring the gap width allows varying of the strength of the coupling coefficient and therefore allows flexible apodization schemes for the input and output of the grating. As the gap is gradually decreased, according to the raised cosine function in Equation 1 above, for a simple and effective apodization resulting in minimal insertion losses and out of band ripple.

In addition, the grating pitch (Λ, the period of pillar positioning) may be used to tune the spectral position of the bandgap as Bragg wavelength is given by λ_{B}=2n_{eff}×Λ. The present grating structure may be tolerant to fabrication errors due to its cladding modulated design and it is structurally robust due to its upper- and under-cladding.

As also described above, a CMOS-compatible USRN possessing a material composition of Si₇N₃ may be used. By tuning the silicon to nitrogen ratio, the USRN bandgap (2.1 eV) was produced with a large nonlinear index (n₂=2.8×10⁻¹³ cm₂W⁻¹, an order of magnitude larger than stoichiometric silicon nitride) having an absence of detrimental two-photon absorption effects at telecommunication wavelengths. The USRN also has a large refractive index, n=3.1, allowing the tight confinement of light and hence flexible dispersion engineering through geometric optimization of the waveguide dimensions.

The present photonic devices may be fabricated on a silicon substrate with a 10 μm SiO₂ thermal oxide layer. The USRN layer may be deposited using inductively-coupled chemical vapor deposition at a low temperature of 250° C. with a thickness of 300 nm. The grating and waveguide structure may be patterned using electron-beam lithography and inductively coupled plasma etching, which may then be followed by 2 μm SiO2 cladding deposition using atomic layer deposition or plasma-enhanced chemical vapor deposition

According to various aspects, the transmission characteristics of the present two-stage device may be measured using an amplified spontaneous emission or ASE source. The transmission plot shows the bandgap at the Bragg wavelength of A_{B}=1567 nm. At the blue side of the bandgap, the increasing group index due to the photonic bandgap generates a large anomalous dispersion.

According to some aspects, the dispersion characteristics for the present Bragg grating was measured using a component analyzer that utilizes time of flight, with a longer grating for convenience, due to larger group delay difference. Group velocity dispersion (GVD), third and fourth-order dispersion are as follows for the grating; β₂=−0.81 ps²/mm, β₃=0.83 ps³/mm, β₄=−0.33 ps⁴/mm. For the channel waveguide, the calculated dispersion for the quasi-TE mode is β₂=−1.24 10⁻³ ps²/mm, β₃=−5.3 10⁻⁸ ps³/mm, β₄=2.4 10⁻⁸ ps⁴/mm. These parameters are essential for simulating the spectral broadening in the cascaded grating-waveguide.

According to various other aspects, dispersion plays a key role in ultrashort pulse propagation in waveguides. The dominant effects in pulse propagation inside a nonlinear waveguide can be understood by comparing the nonlinear length, L_{NL}=(γ P₀)⁻¹ and dispersion length L_{D}=T₀²/|β₂|. These two quantities define the length scales in which the nonlinear and dispersive effects are significant. The soliton number, N²=L_{D}/L_{NL}, is a dimensionless parameter indicating the relative importance of GVD and SPM effects. When L_{D} and L_{NL} are comparable and dispersion is anomalous, the waveguide can support soliton propagation. Both dispersion and nonlinearity play an equally important role in soliton propagation, and they may lead to periodic evolution of pulse shape, initial compression, splitting into breathers and recovering its shape, as found for the experimental conditions, L_{D}=1.1 mm, L_{NL}=0.15 mm, hence N=2.74.

The soliton propagation in the present nonlinear waveguides can be modeled by solving the generalized nonlinear Schrödinger equation (GNLSE), i.e., Equation 2 above, assuming a slowly varying pulse envelope, A(z,t), using a split-step Fourier method to interpret the underlying physics. As noted above, the right-hand side of Equation 2 takes into account effects from self-phase modulation (SPM). γ_{eff} denotes the effective nonlinear parameter and is calculated as

$${γ}_{eff} = \frac{{ω}_{o} {n}_{2}}{λ {A}_{eff}} {( \frac{{n}_{g}}{{n}_{o}} )}^{2} ,$$

where ω₀ is the frequency of the pulse, n_{g} is the group index and nₒ is the refractive index of the material. The effective area (A_{eff}) is engineered to be small to maximize the magnitude of γ_{eff} Since nonlinear losses are negligible at optical intensities up to 50 GW/cm², only take the linear propagation losses, α, into account for the modeling for the present USRN two-stage device.

The temporal plots from modeling show the periodic soliton propagation when the soliton number, N, is 2.74, and only GVD and SPM effects are present along two dispersion lengths for calculations using the specified grating parameters and a hyperbolic-secant input pulse with a full-width half-maximum of 1.68 ps. When high order soliton propagation is perturbed by higher-order dispersive effects, the pulse can temporally break up into its constituent fundamental solitons, or breathers, as third-order dispersion (TOD) breaks the symmetry of periodic pulse evolution throughout the waveguide length. The soliton fission length, i.e., L_{fiss}˜L_{D}/N=0.41 mm, is smaller than the grating length of 1 mm.

In the present two-stage device design, the soliton fission may be harnessed at the initial grating stage caused by the TOD perturbation. The soliton fission process generates temporally narrow pulses, which may then facilitate large spectral broadening when propagating through the highly nonlinear channel waveguide. Incorporating a cladding modulated Bragg gratings with a nonlinear waveguide boosts the supercontinuum generation without the need to use sub-picosecond pulses as the grating itself facilitates the formation of much shorter pulses before they enter the channel waveguide. The nonlinear waveguide encounters much shorter pulses due to the soliton fission and therefore spectral broadening is increased considerably compared to a reference waveguide of the same total length. Input pulses close to the grating band edge may be used to first undergo soliton fission due to the combination of a highly nonlinear material platform and large anomalous dispersion.

According to some aspects, prerequisites to initiating the soliton fission may be to exceed the aforementioned fission length L_{fiss} of 0.41 mm and for TOD induced soliton fission, to have a large β parameter defined as β equals β₃/6β₂T₀. For experimental conditions used in the present disclosure, β equals 0.18, which exceeded the threshold value reported in the literature from soliton theory.

A fiber laser emitting hyperbolic-secant pulses with a 20 MHz repetition rate may be used. Using an autocorrelator, the measured pulse full-width half-maximum may be 1.68 ps. These picosecond pulses were adjusted for a quasi-TE polarization before coupling into a cascaded two-stage nonlinear grating structure and waveguide using tapered fibers. Pulses having a coupled input peak power of 5.47 W may be used, and to characterize the output an optical spectrum analyzer (OSA) with a measurement range of 600 nm-1700 nm may be used. The −30 dB spectral widths for the source, reference waveguide, and the present nonlinear Bragg grating and nonlinear waveguide structures are 17.7 nm, 79.1 nm, 87.2 nm, and 311.2 nm, respectively, as seen in FIG. 5. This indicates a four times (4×) enhancement for the grating with λ_{B}=1567 nm compared to the reference waveguide. The output spectral broadening of the structure having λ_{B}=1588 nm is given to constitute a demonstration of negligible grating effects far away from the band edge whereas close to the band edge may have significant enhancement in the spectral broadening due to the TOD induced soliton fission.

Accordingly, the CMOS-compatibility of the present nonlinear Bragg grating and nonlinear waveguide structures may be ideally suited for harnessing grating dispersion for supercontinuum generation in numerous applications using integrated photonic chips. It may be able to generate supercontinuum on a chip with lower power and/or longer pulse widths having low nonlinear losses using soliton fission in a controllable manner.

In the specification, the term “comprising” shall be understood to have a broad meaning similar to the term “including” and will be understood to imply the inclusion of a stated integer or step or group of integers or steps but not the exclusion of any other integer or step or group of integers or steps. This definition also applies to variations on the term “comprising” such as “comprise” and “comprises”.

The term “coupled” (or “connected”) herein may be understood as electrically coupled or as mechanically coupled, for example, attached or fixed or attached, or just in contact without any fixation, and it will be understood that both direct coupling or indirect coupling (in other words: coupling without direct contact) may be provided.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated photonic chip comprising:
a substrate;
a nonlinear Bragg grating on the substrate, wherein the nonlinear Bragg grating is coupled to an optical pulse source; and
a nonlinear waveguide coupled to the nonlinear Bragg grating.

2. The integrated photonic chip of claim 1, wherein the nonlinear Bragg grating comprises two nonlinear rows of columnated-structures and an elongated structure, wherein the elongated structure separates the two nonlinear rows of columnated-structures.

3. The integrated photonic chip of claim 1, wherein the nonlinear Bragg grating comprises an elongated structure with periodic holes, sidewall modulations or a corrugated top surface.

4. The integrated photonic chip of claim 1, wherein the nonlinear Bragg grating is formed of a material selected from the group consisting of ultra-silicon rich nitrides, silicon nitrides, silicon oxynitrides, silicon-rich nitrides, gallium arsenide, group III-V materials, silicon, group IV materials, and chalcogenides.

5. The integrated photonic chip of claim 1, wherein the nonlinear waveguide is formed of a material selected from the group consisting of ultra-silicon rich nitrides, silicon nitrides, silicon oxynitrides, silicon-rich nitrides, gallium arsenide, group III-V materials, silicon, group IV materials, and chalcogenides.

6. The integrated photonic chip of claim 1, wherein the nonlinear Bragg grating and the nonlinear waveguide are monolithically integrated.

7. A method for generating a broadband supercontinuum comprising:
providing optical pulses of a predetermined wavelength;
inputting the optical pulses through a nonlinear Bragg grating to effect apodization;
passing the optical pulses through a nonlinear waveguide to effect soliton propagation; and
outputting from the nonlinear waveguide generated octave-spanning optical pulses.

8. The method for generating a broadband supercontinuum of claim 7, wherein the inputting of the optical pulse through the nonlinear Bragg grating initiates soliton fission at a photonic band edge to produce shortening of the optical pulses and further comprising:
tuning the photonic band edge by adjusting operating temperature or optical properties.

9. The method for generating a broadband supercontinuum of claim 7, further comprising the nonlinear Bragg grating having two nonlinear rows of column structures having tunable pitches between the columns to adjust the octave-spanning optical pulse's spectral position.

10. A photonic device comprising:
a substrate;
a first silicon dioxide layer forming a lower cladding on the substrate;
a nonlinear Bragg grating structure having an ultra-silicon rich nitride elongated structure between two nonlinear rows of columnated structures on the first silicon dioxide layer;
a nonlinear waveguide structure that is co-planar with the ultra-silicon rich nitride elongated structure on the first silicon dioxide layer; and
a second silicon dioxide layer forming an upper cladding over the nonlinear Bragg grating structure and the non-linear waveguide structure.

11. The photonic device of claim 10, wherein the ultra-silicon rich nitride elongated structure has a composition of Si₇N₃.

12. The photonic device of claim 10, wherein the ultra-silicon rich nitride elongated structure has a thickness in the range of approximately 200 to 600 μm.

13. The photonic device of claim 10, wherein the nonlinear waveguide structure is an extension of the ultra-silicon rich nitride elongated structure has a length in the range of approximately 1 mm to 10 mm.

14. The photonic device of claim 11, wherein the two nonlinear rows of columnated-structures are made of the same material as the ultra-silicon rich nitride elongated structure.

15. The photonic device of claim 10, wherein the two nonlinear rows of column structures have a length in the range of approximately 200 μm to 10 mm.

16. The photonic device of claim 10, wherein the two nonlinear rows of columnated-structures further comprises at least one portion on each row that is bow-curved inwardly towards the ultra-silicon rich nitride elongated structure is positioned therebetween.

17. The photonic device of claim 10, further comprising each of the two nonlinear rows of columnated-structures having a proximal end positioned approximately 50 to 100 nm from the ultra-silicon rich nitride elongated structure and a middle portion positioned approximately 20 to 150 nm from the ultra-silicon rich nitride elongated structure.

18. The photonic device of claim 10, wherein the two nonlinear rows of column structures have an adjustable grating pitch in the range of approximately 300 to 500 nm.

19. The photonic device of claim 10, wherein the first silicon dioxide layer has a thickness in the range of approximately 2 um to 20 um.

20. The photonic device of claim 10, wherein the second silicon dioxide layer has a thickness in the range of approximately 3 um to 20 um.
